(19) United States
(12) Patent Application Publication
(10) Pub. No.: US 2022/0320008 A1
(43) Pub. Date: Oct. 6, 2022

(54) MODULE

(71) Applicant: Murata Manufacturing Co., Ltd., Kyoto-fu (JP)

(72) Inventors: Takafumi KUSUYAMA, Nagaokakyo-shi (JP); Tadashi NOMURA, Nagaokakyo-shi (JP); Yoshihito OTSUBO, Nagaokakyo-shi (JP)

(21) Appl. No.: 17/807,930

(22) Filed: Jun. 21, 2022

Related U.S. Application Data
(63) Continuation of application No. PCT/JP2020/046234, filed on Dec. 11, 2020.

(30) Foreign Application Priority Data
Dec. 27, 2019 (JP) 2019-238354

(51) Int. Cl. H01L 23/552; H01L 25/10

(52) U.S. Cl. CPC H01L 23/552; H01L 25/105; H01L 23/49822

(57) ABSTRACT

A module includes a main board including a first surface, a submodule mounted on the first surface, a first component mounted on the first surface separately from the submodule, a first sealing resin formed so as to cover the first surface, the submodule, and the first component, and an external shield film formed so as to cover a surface and a side surface of the first sealing resin on a side far from the first surface and a side surface of the main board. The submodule includes a second component, a second sealing resin disposed so as to cover the second component, and an internal shield film formed so as to cover at least a part of a side surface of the second sealing resin. The internal shield film has at least a two-layer structure.

### CROSS REFERENCE TO RELATED APPLICATION

This is a continuation of International Application No. PCT/JP2020/046234 filed on Dec. 11, 2020 which claims priority from Japanese Patent Application No. 2019-238354 filed on Dec. 27, 2019. The contents of these applications are incorporated herein by reference in their entireties.

### BACKGROUND OF THE DISCLOSURE

### Field of the Disclosure

The present disclosure relates to a module.

### Description of the Related Art

Japanese Patent No. 5517379 (PTL 1) discloses a module having a structure in which a component is mounted on a circuit board, sealed with a sealing resin, and further formed with a shield. In PTL 1, in the sealing resin, a trench formed between a plurality of mounting components is filled with a conductive material. The shield includes an external shield portion disposed so as to cover an upper surface and a side surface of the sealing resin and an internal shield portion formed of a conductive material in the trench.

PTL 1: Japanese Patent No. 5517379

### BRIEF SUMMARY OF THE DISCLOSURE

In the configuration described in PTL 1, after the sealing resin is formed, the trench is formed by irradiating the sealing resin with a laser beam. When the trench is formed in this way, actually a process of further cleaning an inside of the trench is also required. In this case, the number of processes increases and becomes complicated.

Accordingly, an object of the present disclosure is to provide a module that can prevent mutual interference of noise between internal components and be easily manufactured.

In order to achieve the above object, a module according to one aspect of the present disclosure includes: a main board including a first surface; a submodule mounted on the first surface; a first component mounted on the first surface separately from the submodule; a first sealing resin formed so as to cover the first surface, the submodule, and the first component; and an external shield film formed so as to cover a surface and a side surface of the first sealing resin on a side far from the first surface and a side surface of the main board. The submodule includes a second component, a second sealing resin disposed so as to cover the second component, and an internal shield film formed so as to cover at least a part of a side surface of the second sealing resin. The internal shield film has at least a two-layer structure.

According to the present disclosure, the module can be assembled by previously manufacturing the submodule at another place and then bringing in and mounting the submodule. Furthermore, because the internal shield film is formed on a part of the side surface of the submodule, noise can be prevented from being mixed into the submodule, and mutual interference of the noise between internal components can be prevented. In addition, the module can be easily manufactured.

### BRIEF DESCRIPTION OF THE SEVERAL VIEWS OF THE DRAWINGS

FIG. 1 is a first perspective view illustrating a module according to a first embodiment of the present disclosure.

FIG. 2 is a second perspective view illustrating the module of the first embodiment of the present disclosure.

FIG. 3 is a perspective plan view illustrating the module of the first embodiment of the present disclosure.

FIG. 4 is a sectional view taken along a line IV-IV in FIG. 3.

FIG. 5 is a sectional view illustrating a module according to a second embodiment of the present disclosure.

FIG. 6 is a sectional view illustrating a module according to a third embodiment of the present disclosure.

FIG. 7 is a sectional view illustrating a module according to a fourth embodiment of the present disclosure.

FIG. 8 is a perspective plan view illustrating a module according to a fifth embodiment of the present disclosure.

FIG. 9 is a sectional view taken along a line IX-IX in FIG. 8.

FIG. 10 is a sectional view illustrating a first modification of the module in the fifth embodiment of the present disclosure.

FIG. 11 is a perspective plan view illustrating a second modification of the module in the fifth embodiment of the present disclosure.

FIG. 12 is a sectional view illustrating a module according to a sixth embodiment of the present disclosure.

FIG. 13 is a sectional view illustrating a module according to a seventh embodiment of the present disclosure.

FIG. 14 is a sectional view illustrating a modification of the module in the seventh embodiment of the present disclosure.

FIG. 15 is a sectional view illustrating a module according to an eighth embodiment of the present disclosure.

FIG. 16 is a sectional view illustrating a module according to a ninth embodiment of the present disclosure.

FIG. 17 is a partially enlarged view illustrating the module of the ninth embodiment of the present disclosure.

FIG. 18 is a sectional view illustrating a module according to a tenth embodiment of the present disclosure.

FIG. 19 is a sectional view illustrating a modification of the module in the tenth embodiment of the present disclosure.

FIG. 20 is a sectional view illustrating a module according to an eleventh embodiment of the present disclosure.

FIG. 21 is a partially enlarged view illustrating the module of the eleventh embodiment of the present disclosure.

FIG. 22 is an explanatory view illustrating a first process of a method for manufacturing the module of the second embodiment of the present disclosure.

FIG. 23 is an explanatory view illustrating a second process of the method for manufacturing the module of the second embodiment of the present disclosure.

FIG. 24 is an explanatory view illustrating a third process of the method for manufacturing the module of the second embodiment of the present disclosure.

FIG. 25 is an explanatory view illustrating a fourth process of the method for manufacturing the module of the second embodiment of the present disclosure.

FIG. 26 is an explanatory view illustrating a fifth process of the method for manufacturing the module of the second embodiment of the present disclosure.

FIG. 27 is an explanatory view illustrating a sixth process of the method for manufacturing the module of the second embodiment of the present disclosure.

FIG. 28 is an explanatory view illustrating a seventh process of the method for manufacturing the module of the second embodiment of the present disclosure.

FIG. 29 is an explanatory view when an internal shield film has a two-layer structure.

FIG. 30 is a partially sectional view illustrating a first example of a positional relationship between the internal shield film and an external shield film.

FIG. 31 is a partially sectional view illustrating a second example of the positional relationship between the internal shield film and the external shield film.

### DETAILED DESCRIPTION OF THE DISCLOSURE

A dimensional ratio in the drawings does not necessarily represent the actual dimensional ratio, and the dimensional ratio may be exaggerated for the sake of convenience of description. In the following description, when an upper or lower concept is referred to, the upper or lower concept does not necessarily mean absolute upper or lower, but may mean relative upper or lower in an illustrated posture.

### First Embodiment

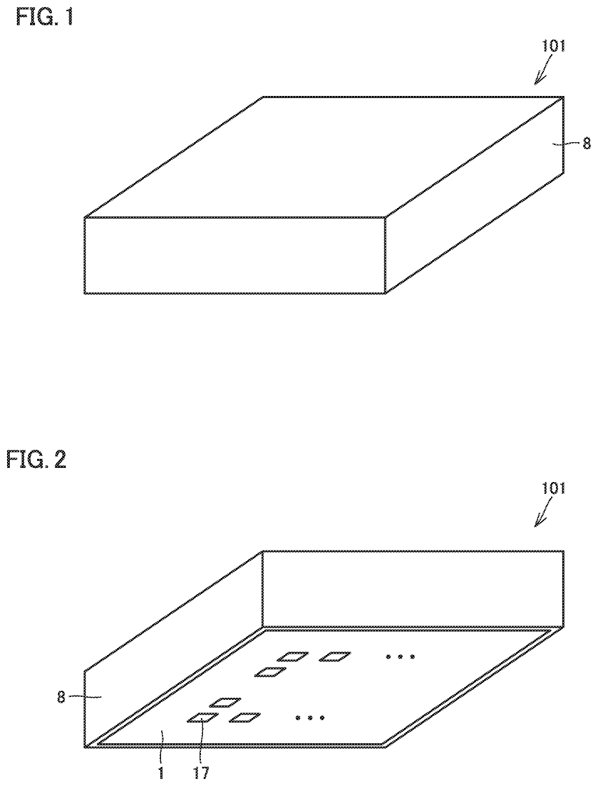

With reference to FIGS. 1 to 4, a module according to a first embodiment of the present disclosure will be described.

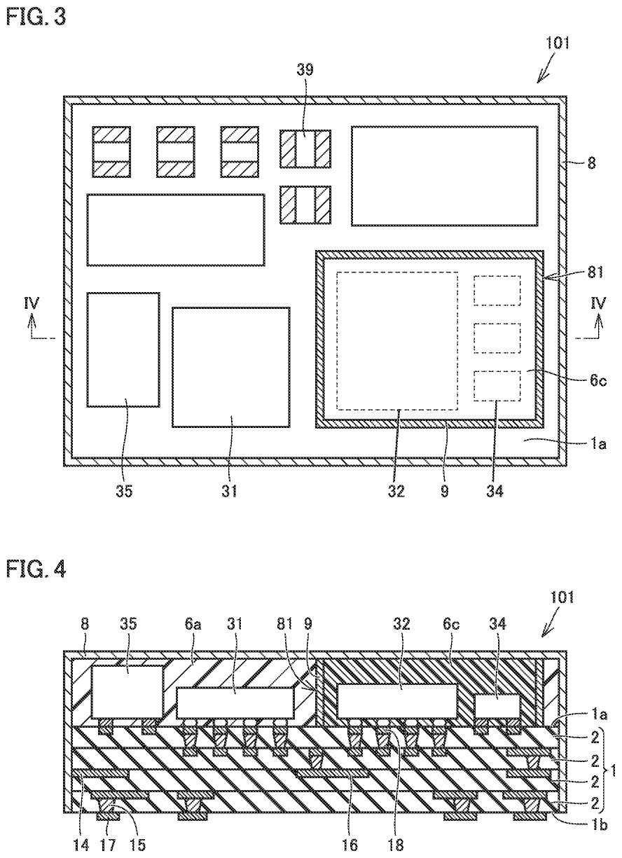

FIG. 1 illustrates a module 101 of the first embodiment. An upper surface and a side surface of module 101 are covered with an external shield film 8. FIG. 2 illustrates module 101 as viewed from obliquely below in FIG. 1. The lower surface of module 101 is not covered with external shield film 8, but a main board 1 is exposed. One or more external terminals 17 are provided on a lower surface of main board 1. The number, size, and array of external terminals 17 in FIG. 2 are merely examples. FIG. 3 is a perspective plan view of module 101. FIG. 3 corresponds to a top view of a state in which the upper surface of external shield film 8 of module 101 and a first sealing resin 6a are removed. A first component 31 is mounted on a first surface 1a of main board 1. In addition to first component 31, components 35, 39 are mounted on first surface 1a. A submodule 81 is also mounted on first surface 1a. Submodule 81 includes a second sealing resin 6c. The component covered with second sealing resin 6c is indicated by a broken line.

For example, first component 31 may be an integrated circuit (IC). More specifically, for example, first component 31 may be a low noise amplifier (LNA). FIG. 4 is a sectional view taken along a line Iv-Iv in FIG. 3. Wiring may be provided on a surface or an inside of main board 1. Main board 1 may be a resin board or a ceramic board. Main board 1 may be a multilayer board. In the example of FIG. 4, main board 1 is formed by laminating a plurality of insulating layers 2. For example, insulating layer 2 is a resin layer.

Module 101 in the first embodiment includes main board 1 including first surface 1a, a submodule 81 mounted on first surface 1a, first component 31 mounted on first surface 1a separately from submodule 81, first sealing resin 6a formed so as to cover first surface 1a, submodule 81, and first component 31, and external shield film 8 formed so as to cover a surface and a side surface of first sealing resin 6a on a side far from first surface 1a and a side surface of main board 1. Submodule 81 is formed so as to have a smaller area than that of main board 1. Submodule 81 includes a second component 32, second sealing resin 6c disposed so as to cover second component 32, and an internal shield film 9 formed so as to cover at least one of side surfaces of second sealing resin 6c.

As illustrated in FIG. 4, a plurality of pad electrodes 18 are disposed on first surface 1a of main board 1, and first component 31 and second component 32 are mounted using pad electrodes 18. Component 35 is also mounted using pad electrode 18.

As illustrated in FIG. 4, main board 1 includes first surface 1a and a second surface 1b that is a surface opposite to first surface 1a. The shape, number, arrangement, and the like of the components illustrated here are merely examples. In the example illustrated here, first component 31, component 35, and the like are sealed with first sealing resin 6a.

Submodule 81 includes a component 34 in addition to second component 32. Component 34 is also mounted using pad electrode 18. A ground conductor pattern 14 is disposed inside main board 1. Ground conductor pattern 14 is exposed to the side surface of main board 1 and electrically connected to external shield film 8. Main board 1 includes a conductor via 15 and a conductor pattern 16. Conductor via 15 is electrically connected to external terminal 17. Conductor via 15 and conductor pattern 16 are appropriately disposed to form a circuit. Ground conductor pattern 14 is grounded through a circuit (not illustrated) inside main board 1.

In the first embodiment, second component 32 is disposed inside submodule 81 and internal shield film 9 is disposed so as to cover at least one of the side surfaces of second sealing resin 6c, so that second component 32 can be sufficiently shielded. In the first embodiment, exchange of an electromagnetic wave between first component 31 and second component 32 can be blocked by internal shield film 9. Submodule 81 is implemented. That is, submodule 81 is brought and mounted after being previously manufactured in another place. Accordingly, manufacturing is facilitated.

According to the first embodiment, the module that can prevent the mutual interference of the noise between internal components and be easily manufactured can be provided.

In the first embodiment, as illustrated in FIG. 4, internal shield film 9 does not cover the upper surface of second sealing resin 6c. Such the configuration can be obtained as follows. When submodule 81 is prepared, internal shield film 9 is formed by sputtering or the like so as to cover the upper surface and the side surface of second sealing resin 6c. Submodule 81 is mounted on first surface 1a of main board 1, and first sealing resin 6a is disposed. Thereafter, the upper surface of submodule 81 is scraped together with the upper surface of first sealing resin 6a by polishing. Thus, the portion of internal shield film 9 covering the upper surface of second sealing resin 6c is removed. Thereafter, external shield film 8 is formed.

As described in the first embodiment, preferably, second component 32 is disposed along the surface of submodule 81 closer to first surface 1a, and mounted on first surface 1a. By adopting this configuration, submodule 81 can be thinned, and a height of the entire module can be reduced.

As described in the first embodiment, preferably, internal shield film 9 does not cover the surface of second sealing resin 6c on the side far from first surface 1a, and external shield film 8 directly covers the surface of second sealing resin 6c on the side far from first surface 1a. First sealing resin 6a is not disposed above submodule 81 by adopting this configuration, so that the height of the entire module can be reduced.

### Second Embodiment

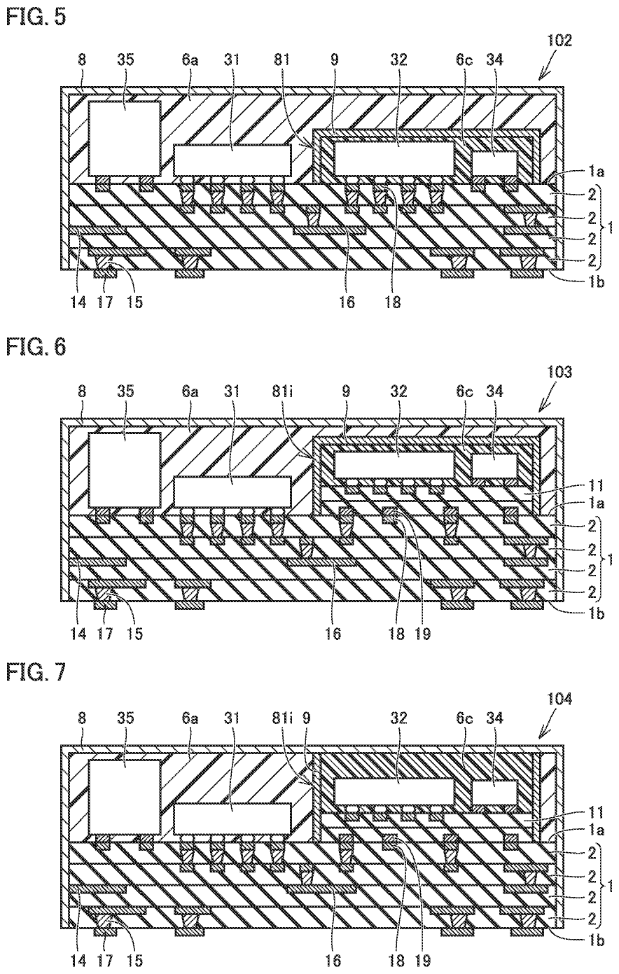

With reference to FIG. 5, a module according to a second embodiment of the present disclosure will be described. FIG. 5 is a sectional view illustrating a module 102 of the second embodiment. Module 102 is common to module 101 in a basic configuration, but differs from module 101 in the following points.

In module 102, internal shield film 9 further covers not only the side surface of second sealing resin 6c but also the surface on the side far from first surface 1a. Accordingly, internal shield film 9 and external shield film 8 are doubly disposed on the side far from first surface 1a as viewed from the component built in submodule 81.

Also in the second embodiment, the effect similar to that of the first embodiment can be obtained. In the second embodiment, the surface on the side far from first surface 1a of the component built in submodule 81 can be doubly shielded, so that the electromagnetic wave can be sufficiently shielded and the module with high reliability can be implemented.

### Third Embodiment

With reference to FIG. 6, a module according to a third embodiment of the present disclosure will be described. FIG. 6 is a sectional view illustrating a module 103 of the third embodiment. Module 103 is common to module 102 in the basic configuration, but differs from module 102 in the following points.

Module 103 includes a submodule 81i instead of submodule 81. Submodule 81i includes a submodule board 11, second component 32 is mounted on the surface of submodule board 11 on the side far from first surface 1a, and submodule board 11 is mounted on first surface 1a. Submodule board 11 includes a connection terminal 19 on the surface facing main board 1. Connection terminal 19 is electrically connected to pad electrode 18 provided on first surface 1a.

Also in the third embodiment, the effect similar to that of the first embodiment can be obtained. In the third embodiment, submodule 81i includes submodule board 11 as a unique board, so that a unique wiring can be provided in submodule board 11. When the wiring is appropriately provided in this manner, grounding to internal shield film 9 can also be performed. In addition, when submodule 81i is manufactured, the component can be mounted on submodule board 11, which facilitates the manufacturing.

### Fourth Embodiment

With reference to FIG. 7, a module according to a fourth embodiment of the present disclosure will be described. FIG. 7 is a sectional view illustrating a module 104 of the fourth embodiment. Module 104 is common to module 101 in the basic configuration, but differs from module 101 in the following points.

In module 104, similarly to the first embodiment, internal shield film 9 does not cover the surface of second sealing resin 6c on the side far from first surface 1a, and external shield film 8 directly covers the surface of second sealing resin 6c on the side far from first surface 1a. In module 104, similarly to the third embodiment, submodule 81i includes submodule board 11, second component 32 is mounted on the surface of submodule board 11 on the side far from first surface 1a, and submodule board 11 is mounted on first surface 1a.

Also in the fourth embodiment, the effect similar to that of the first and third embodiments can be obtained.

### Fifth Embodiment

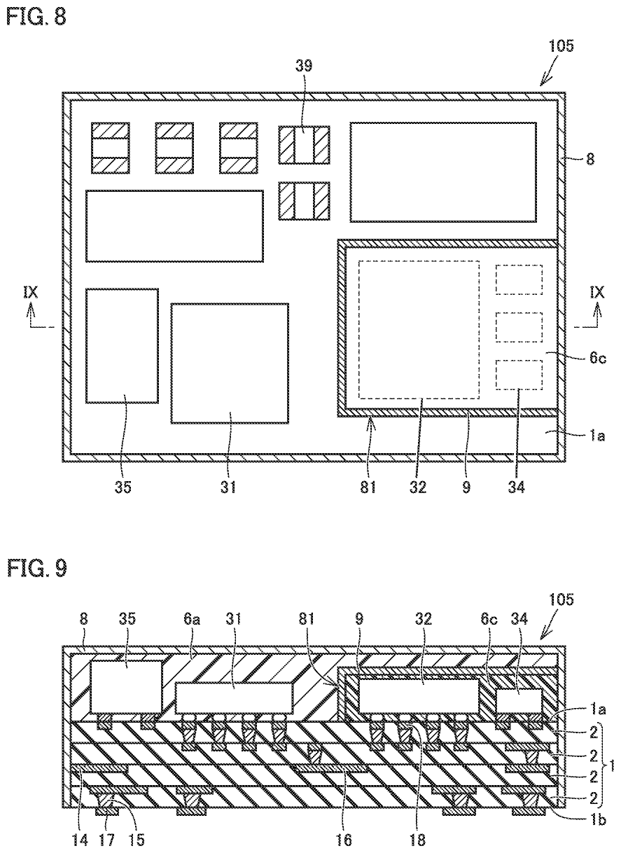

With reference to FIGS. 8 and 9, a module according to a fifth embodiment of the present disclosure will be described. FIG. 8 is a sectional view illustrating a module 105 of the fifth embodiment. FIG. 8 corresponds to a top view of a state in which the upper surface of external shield film 8 of module 105 is removed, first sealing resin 6a is removed, and the upper surface of internal shield film 9 of submodule 81 is further removed. FIG. 9 is a sectional view taken along a line IX-IX in FIG. 8.

Module 105 is common to module 102 in the basic configuration, but differs from module 105 in the following points.

In module 105, internal shield film 9 does not cover a part of the side surface of second sealing resin 6c, and external shield film 8 directly covers at least a part of a portion of the side surface of second sealing resin 6c that is not covered with internal shield film 9. In the example illustrated here, in FIG. 9, internal shield film 9 does not exist on the right side surface of second sealing resin 6c, and instead, external shield film 8 directly covers this side surface.

Also in the fifth embodiment, the effect similar to that of the second embodiment can be obtained. In the fifth embodiment, submodule 81 can be disposed at the endmost in module 105, so that a mountable space on first surface 1a of main board 1 can be saved.

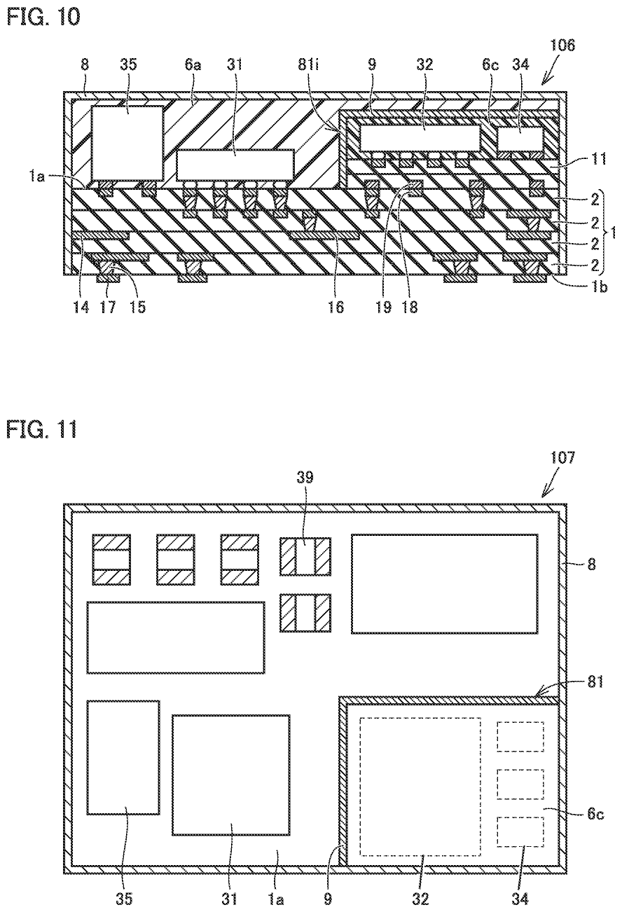

As in a module 106 of FIG. 10, a submodule 81i may be mounted instead of submodule 81. Submodule 81i includes submodule board 11. Not only a part of the side surface of second sealing resin 6c is covered with external shield film 8, but also one side surface of submodule board 11 is covered with external shield film 8.

Such the configuration can be obtained by the following method. When submodule 81i is prepared, internal shield film 9 is once formed so as to cover the upper surface and all the side surfaces. Submodule 81i is mounted on first surface 1a of main board 1. Then, first sealing resin 6a is disposed so as to seal first component 31, component 35, and submodule 81i. First sealing resin 6a is cut into individual product sizes with a dicer or the like. At this time, a portion covering the side surface of a part of second sealing resin 6c is also scraped. Thereafter, external shield film 8 is formed.

In the fifth embodiment, an example in which three of the four side surfaces of submodule 81 are covered with internal shield film 9 in planar view is illustrated as illustrated in FIG. 8, but this is merely an example. For example, as in a module 107 of FIG. 11, two of the four side surfaces of submodule 81 may be covered with internal shield film 9 in planar view. In module 107, as illustrated in FIG. 11, submodule 81 is disposed so as to be close to one corner of module 107. With such the disposition, the mountable space on first surface 1a of main board 1 can be saved.

### Sixth Embodiment

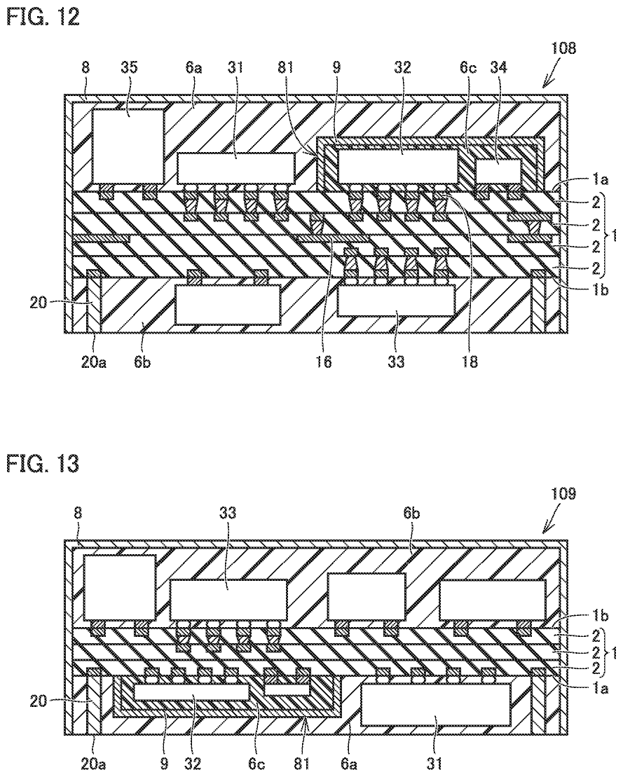

With reference to FIG. 12, a module according to a sixth embodiment of the present disclosure will be described. FIG. 12 is a sectional view illustrating a module 108 of the sixth embodiment. Module 108 is common to module 102 in the basic configuration.

In module 108, main board 1 includes second surface 1b as the surface opposite to first surface 1a. Module 108 includes a third component 33 mounted on second surface 1b.

Components other than third component 33 may also be mounted on second surface 1b. A third sealing resin 6b is disposed so as to cover second surface 1b and the components mounted on second surface 1b. A columnar conductor 20 is disposed on second surface 1b. Columnar conductor 20 penetrates third sealing resin 6b. An end surface 20a of columnar conductor 20 on the side far from second surface 1b is exposed from third sealing resin 6b and serves as the external terminal.

Also in the sixth embodiment, the effect similar to that of the second embodiment can be obtained. In the sixth embodiment, the component is also mounted on second surface 1b, so that more components can be mounted. Even when main board 1 having a limited area is used, high density mounting of module 108 as a whole can be performed by mounting many components on both surfaces of main board 1.

### Seventh Embodiment

With reference to FIG. 13, a module according to a seventh embodiment of the present disclosure will be described. FIG. 13 is a sectional view illustrating a module 109 of the seventh embodiment. In module 109, a positional relationship between first surface 1a and second surface 1b is reversed as compared with the previous embodiments. That is, in FIG. 13, the lower surface is first surface 1a, and the upper surface is second surface 1b. Accordingly, the positional relationship between first sealing resin 6a and third sealing resin 6b is also reversed as compared with the previous embodiments.

Module 109 includes main board 1 including first surface 1a and second surface 1b that is the surface opposite to first surface 1a, submodule 81 that is formed in a smaller area than main board 1 and mounted on first surface 1a, first component 31 mounted on first surface 1a separately from submodule 81, and first sealing resin 6a formed to cover first surface 1a, submodule 81, and first component 31. Submodule 81 includes second component 32, second sealing resin 6c disposed so as to cover second component 32, and internal shield film 9 formed so as to cover at least one of side surfaces of second sealing resin 6c. Module 109 further includes third component 33 mounted on second surface 1b, third sealing resin 6b formed so as to cover second surface 1b and third component 33, and external shield film 8 formed so as to cover the side surface of first sealing resin 6a, the side surface of main board 1, and the surface and the side surface of third sealing resin 6b on the side far from second surface 1b.

In the seventh embodiment, when module 109 is mounted on a mother board or the like, submodule 81 is disposed on the surface facing the mother board. Even such the configuration, the effects described in the above embodiments can be obtained.

As described in the seventh embodiment, preferably, second component 32 is disposed along the surface of submodule 81 closer to first surface 1a, and mounted on first surface 1a. By adopting this configuration, submodule 81 can be thinned, and a height of the entire module can be reduced.

(Modification)

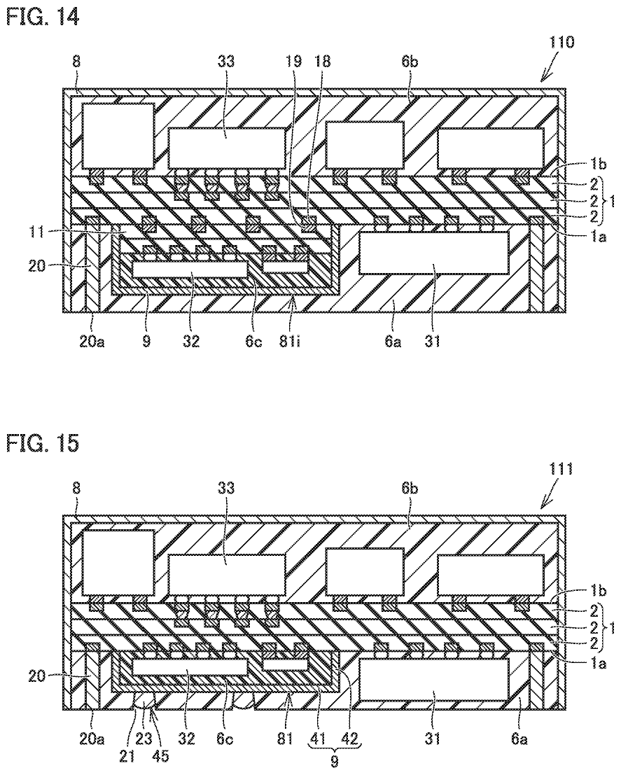

In the seventh embodiment, module 109 includes submodule 81 not including its own submodule board, but may include a submodule including its own submodule board instead of submodule 81. That is, a module 110 in FIG. 14 may be used. Module 110 includes submodule 81i. In module 110, submodule 81i includes submodule board 11, second component 32 is mounted on the surface of submodule board 11 on the side far from first surface 1a, and submodule board 11 is mounted on first surface 1a. The effect as described in the third embodiment can be obtained by adopting this configuration.

### Eighth Embodiment

With reference to FIG. 15, a module according to an eighth embodiment of the present disclosure will be described. FIG. 15 is a sectional view illustrating a module 111 of the eighth embodiment. Module 111 has the following configuration. Module 111 is similar to module 109 (see FIG. 13) described in the seventh embodiment, and the items already described in the seventh embodiment will not be described again.

Internal shield film 9 includes an internal shield top surface portion 41 that covers the surface of second sealing resin 6c on the side far from first surface 1a. Internal shield film 9 includes a side surface portion 42 that covers the side surface of second sealing resin 6c in addition to internal shield top surface portion 41. Module 111 includes a ground connection conductor 45 electrically connected to internal shield top surface portion 41. Ground connection conductor 45 penetrates first sealing resin 6a. Ground connection conductor 45 is exposed to the outside of module 111. An opening 21 is formed in a portion of first sealing resin 6a that covers internal shield top surface portion 41. Ground connection conductor 45 is disposed inside opening 21. In the example illustrated here, ground connection conductor 45 includes a solder bump 23. That is, solder bump 23 is disposed in opening 21. Solder bump 23 is electrically connected to internal shield top surface portion 41.

In the eighth embodiment, internal shield film 9 includes internal shield top surface portion 41, so that shielding performance can be improved with respect to the lower side of module 111 in FIG. 15. In the eighth embodiment, internal shield film 9 can be grounded through ground connection conductor 45, and ground connection conductor 45 is not directly connected to main board 1 but connected to shield top surface portion 41. Therefore, an opening that reaches main board 1 is not required to be formed by laser processing, and a film that receives the laser beam is not required on first surface 1a of main board 1. Thus, a region where the wiring can be freely disposed can be largely secured on first surface 1a. In the eighth embodiment, the grounding of internal shield film 9 can be performed through ground connection conductor 45, and the wiring is not required to be provided inside main board 1 in order to ground internal shield film 9, so that the degree of freedom in designing main board 1 is improved.

As described in the eighth embodiment as an example, ground connection conductor 45 may include solder bump 23. The electrical connection can be easily implemented by adopting this configuration.

### Ninth Embodiment

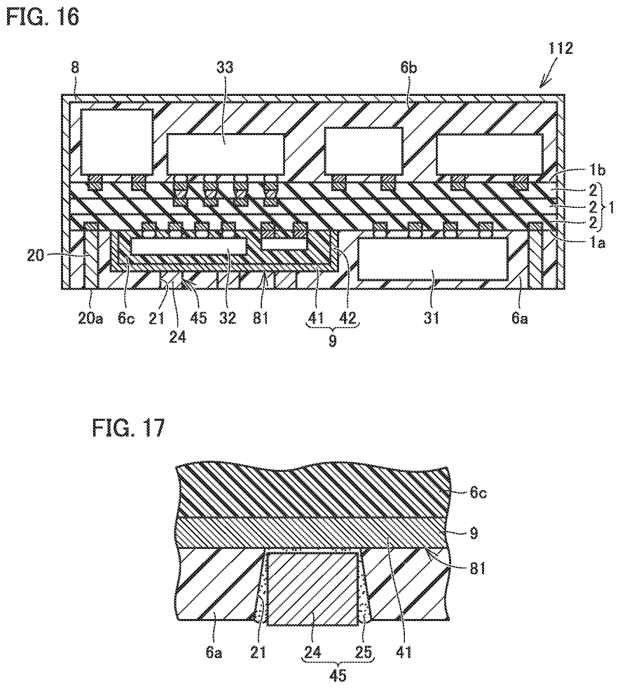

With reference to FIGS. 16 and 17, a module according to a ninth embodiment of the present disclosure will be described. FIG. 16 is a sectional view illustrating a module 112 of the ninth embodiment.

Module 112 includes ground connection conductor 45 electrically connected to internal shield top surface portion 41. Ground connection conductor 45 includes a metal pin or a metal block. In the example illustrated here, ground connection conductor 45 includes a metal block 24. Metal block 24 is disposed inside opening 21 provided in first sealing resin 6a. FIG. 17 is an enlarge view illustrating metal block 24 and the vicinity thereof in FIG. 16. As illustrated in FIG. 17, the side surface of opening 21 may have a tapered shape that expands toward the outside. For example, opening 21 may be formed by laser processing. Solder 25 is disposed inside opening 21. Metal block 24 is electrically connected to internal shield film 9 through solder 25. Solder 25 may also be disposed between the side surface of opening 21 and metal block 24. The end of metal block 24 on the side farthest from internal shield film 9 may be in the same plane as the surface of first sealing resin 6a, or protrude from the surface of first sealing resin 6a.

Also in the ninth embodiment, the effect similar to that of the eighth embodiment can be obtained. Although the example in which ground connection conductor 45 includes metal block 24 has been described here, the metal pin may be used instead of metal block 24.

### Tenth Embodiment

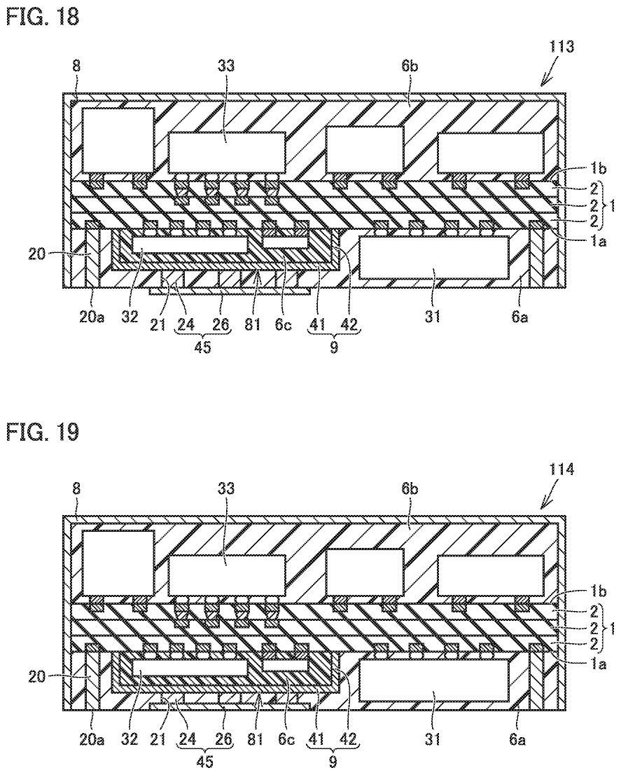

With reference to FIG. 18, a module according to a tenth embodiment of the present disclosure will be described. FIG. 18 is a sectional view illustrating a module 113 of the tenth embodiment.

Module 113 includes ground connection conductor 45 electrically connected to internal shield top surface portion 41. Ground connection conductor 45 includes a ground conductor film 26 extending along the surface of first sealing resin 6a on the side far from main board 1. Ground conductor film 26 is electrically connected to the metal pin or the metal block. In the example illustrated here, because metal block 24 is used, ground conductor film 26 is electrically connected to metal block 24. As exemplified herein, one ground conductor film 26 may be connected across a plurality of metal blocks 24. Ground conductor film 26 may be formed by printing or the like. Ground conductor film 26 may be formed by attaching a member previously formed in a plate shape.

Also in the tenth embodiment, the effect similar to that of the eighth embodiment can be obtained. In the tenth embodiment, because ground connection conductor 45 includes ground conductor film 26, when module 113 is mounted on the mother board or the like, tolerance for misalignment is increased, and the electric connection can be performed more certainly.

(Modification)

A module 114 illustrated in FIG. 19 may be used. Module 114 is common to module 113 in that ground connection conductor 45 includes metal block 24 and ground conductor film 26. In module 114, a recess is formed on the surface of first sealing resin 6a, and ground conductor film 26 is disposed inside the recess. As a result, the surface of ground conductor film 26 and the surface of first sealing resin 6a are substantially in the same plane. Also in module 114, the same effect as that of module 113 can be obtained.

### Eleventh Embodiment

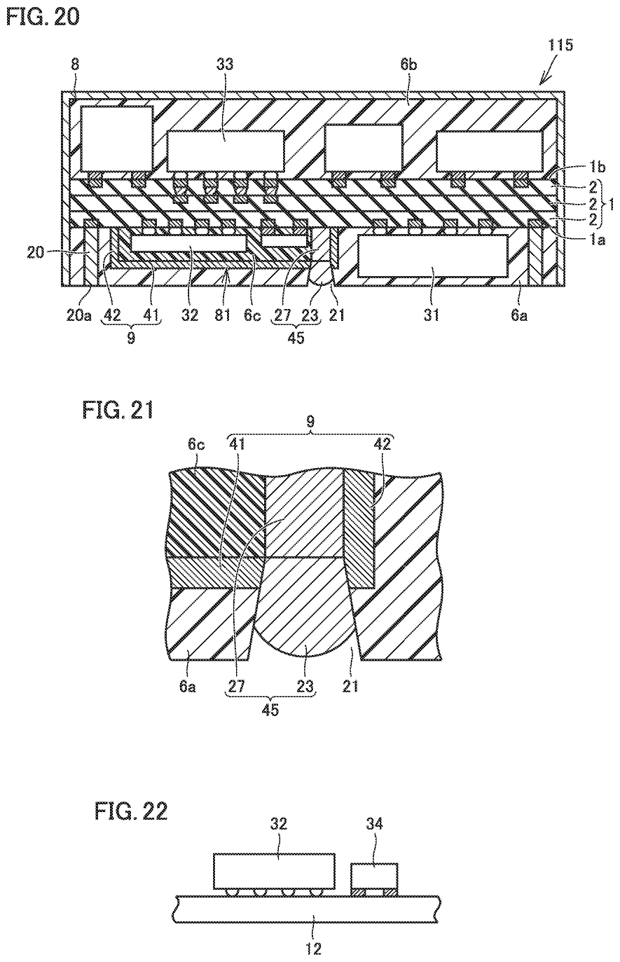

With reference to FIG. 20, a module according to an eleventh embodiment of the present disclosure will be described. FIG. 20 is a sectional view illustrating a module 115 of the eleventh embodiment.

Module 115 includes ground connection conductor 45 electrically connected to internal shield top surface portion 41. Ground connection conductor 45 includes an internal-submodule ground conductor 27 that abuts on side surface portion 42 as the portion of internal shield film 9 formed to cover the side surface of second sealing resin 6c so as to be electrically connected from the inside of internal shield film 9. Ground connection conductor 45 includes solder bump 23 connected to the end of internal-submodule ground conductor 27 on the side far from first surface 1a. Solder bump 23 penetrates internal shield film 9. Solder bump 23 is exposed to the outside of module 115. FIG. 21 is an enlarged view illustrating solder bump 23 and the vicinity thereof in FIG. 20. The lower end of solder bump 23 may be flush with the surface of first sealing resin 6a, or may protrude or be recessed from the surface of first sealing resin 6a.

Also in the eleventh embodiment, the effect similar to that of the tenth embodiment can be obtained. In the eleventh embodiment, ground connection conductor 45 includes internal-submodule ground conductor 27, so that ground connection conductor 45 can be connected to internal shield film 9 in a wide area. Accordingly, internal shield film 9 can be grounded more certainly.

With reference to FIGS. 22 to 28, a method for manufacturing module 102 (see FIG. 5) will be described.

As illustrated in FIG. 22, second component 32 is attached to the surface of a carrier tape 12. In addition, some components are attached as necessary. In this case, component 34 is attached as an example. Carrier tape 12 may be a large size corresponding to the plurality of submodules 81.

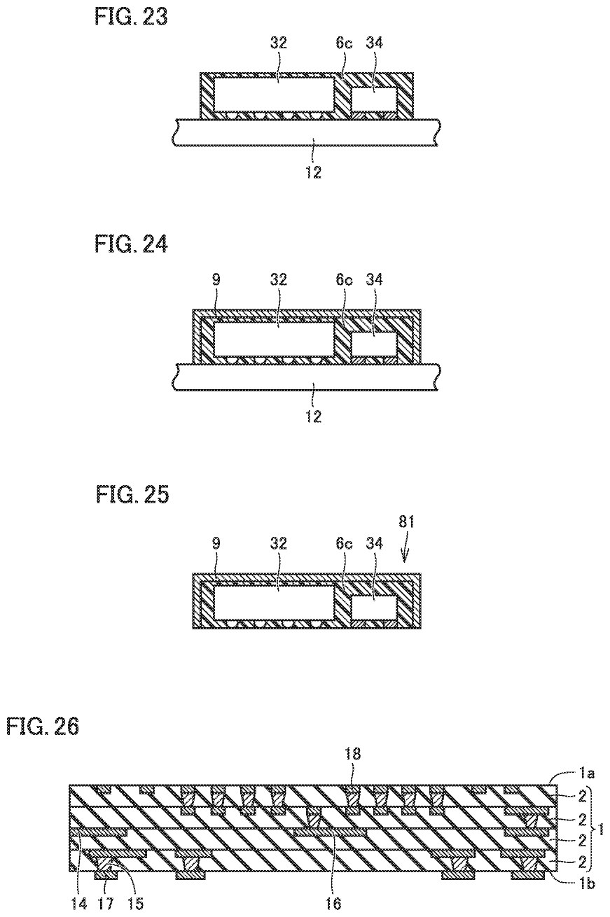

As illustrated in FIG. 23, second sealing resin 6c is formed so as to seal second component 32 and component 34. Second sealing resin 6c may be once integrally formed over a wide area, and cut into sizes corresponding to individual submodules 81.

As illustrated in FIG. 24, internal shield film 9 is formed so as to cover the upper surface and the side surface of second sealing resin 6c. For example, internal shield film 9 can be formed by sputtering. Internal shield film 9 may be a single layer or a laminate of a plurality of layers.

As illustrated in FIG. 25, carrier tape 12 is removed. Thus, submodule 81 is obtained. The connection terminals of second component 32 and component 34 are exposed on the lower surface of submodule 81.

As illustrated in FIG. 26, a plurality of insulating layers 2 are laminated to prepare main board 1. Conductor vias 15 and conductor patterns 16 are appropriately disposed inside main board 1. Ground conductor pattern 14 is disposed so as to be exposed to the side surface of main board 1. Main board 1 is prepared such that pad electrode 18 is exposed on first surface 1a. Main board 1 is prepared such that external terminal 17 is exposed on second surface 1b.

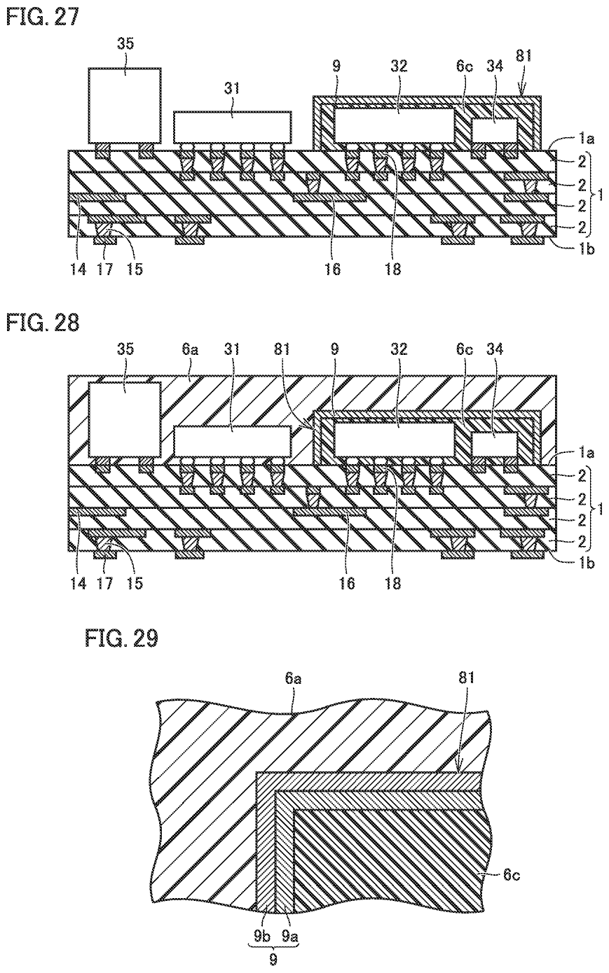

As illustrated in FIG. 27, first component 31, component 35, and submodule 81 are mounted on first surface 1a of main board 1.

First sealing resin 6a is formed as illustrated in FIG. 28. At this point, main board 1 has the size of individual modules at the stages of FIGS. 26 and 27. However, main board 1 may be initially in a collective board state in order to efficiently manufacture a plurality of modules. In this case, required components may be mounted in the state of the collective board, first sealing resin 6a may be formed in the state of the collective board, and then first sealing resin 6a may be cut into individual module sizes.

Furthermore, external shield film 8 is formed. Thus, module 102 in FIG. 5 is obtained.

Internal shield film 9 preferably has a two-layer structure. FIG. 29 is an enlarge view illustrating a part of module 102 in FIG. 5. FIG. 29 is an enlarged view illustrating the vicinity of the corner of submodule 81. Internal shield film 9 in which characteristics of each materials are combined can be obtained by adopting the two-layer structure. In the example of FIG. 29, in the two-layer structure, a stainless steel film 9a and a copper film 9b are stacked in order from the inside. When the two-layer structure is a combination of stainless steel film 9a and copper film 9b as described above, adhesion to second sealing resin 6c can be secured by stainless steel film 9a, and at the same time, good conductivity can be secured by copper film 9b. Internal shield film 9 is not limited to the two-layer structure, but for example, may have a structure in which a stainless steel film for rust prevention is further added to the outside of the two-layer structure described above. That is, internal shield film 9 preferably has at least a two-layer structure, and may have a structure of three or more layers.

Thickness of internal shield film 9 is preferably less than or equal to the thickness of external shield film 8. The entire module can be thinned by adopting this configuration. For example, external shield film 8 may have the three-layer structure in which a stainless steel film, a copper film, and a stainless steel film are stacked in this order. A rust prevention effect is obtained by disposing the stainless steel film on the outermost layer.

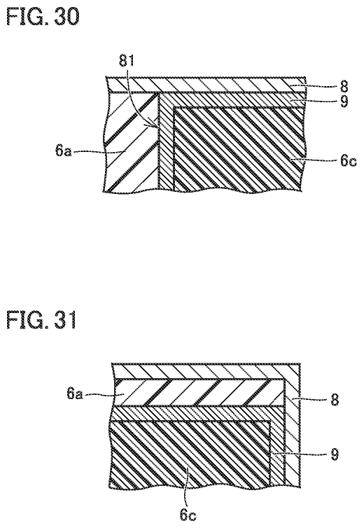

As illustrated in FIG. 30, the module may include a portion where a part of internal shield film 9 and a part of external shield film 8 overlap each other while being in close contact with each other. FIG. 30 is an enlarged view illustrating the vicinity of the corner of submodule 81 in the sectional view of the module. In the example of FIG. 30, a part of external shield film 8 forming the upper surface of the module and a part of internal shield film 9 forming the upper surface overlap each other while being in close contact with each other.

In addition, the module may have a configuration in FIG. 31. In the example of FIG. 31, a part of the portion forming the side surface of the module in external shield film 8 and the portion forming the side surface in internal shield film 9 overlap each other while being in close contact with each other.

In each of the above embodiments, the example in which only one submodule is provided in one module has been described. However, a plurality of submodules may be provided in one module. One or more submodules may each be mounted on both first surface 1a and second surface 1b of main board 1.

First sealing resin 6a and third sealing resin 6b may be the same type of resin or different types of resins. First sealing resin 6a and second sealing resin 6c may be the same type of resin or different types of resins.

In each of the above embodiments, submodule 11 and main board 1 are illustrated while being in close contact with each other. However, normally the solder or the like is disposed between submodule 11 and main board 1 for the electric connection, so that a slight gap is generated between submodule 11 and main board 1 at a portion other than the electric connection portion. In this case, for convenience of description, submodule 11 and main board 1 are illustrated while being in close contact with each other. Actually, submodule 11 and main board 1 may be in close contact with each other or have a slight gap therebetween.

In each of the above embodiments, internal shield film 9 and external shield film 8 are both grounded so as to be able to exhibit a function of shielding the electromagnetic wave. External shield film 8 is grounded by being electrically connected to the ground conductor disposed inside main board 1 in the side surface of main board 1. Internal shield film 9 is also grounded through some path. When internal shield film 9 and external shield film 8 are electrically connected as in modules 101, 104, 105, 106, it can be considered that internal shield film 9 is also grounded by external shield film 8 being grounded. However, even in this case, internal shield film 9 is preferably uniquely electrically connected to some ground conductor. In the configuration in which internal shield film 9 and external shield film 8 are not electrically connected as in modules 102, 103, 108, 109, 110, internal shield film 9 needs to be uniquely electrically connected to some ground conductor. For example, the ground conductor may be the metal pin or the metal block disposed on the surface of main board 1. A land electrode for the ground connection may be provided on the surface of main board 1, and internal shield film 9 may be electrically connected to the land electrode. In the module including submodule board 11, internal shield film 9 may be electrically connected to the ground conductor disposed inside submodule board 11 in the side surface of submodule board 11.

A plurality of the above embodiments may be appropriately combined.

It should be noted that the above embodiments disclosed herein are merely an example in all respects, and are not restrictive. The scope of the present disclosure is indicated by the claims, and all modifications within the meaning and scope of the claims are included in the present disclosure.
1: main board, 1a: first surface, 1b: second surface, 2: insulating layer, 6a: first sealing resin, 6b: third sealing resin, 6c: second sealing resin, 8: external shield film, 9: internal shield film, 9a: stainless steel film, 9b: copper film, 11: submodule board, 12: carrier tape, 14: ground conductor pattern, 15: conductor via, 16: conductor pattern, 17: external terminal, 18: pad electrode, 19: connection terminal, 20: columnar conductor, 20a: lower surface, 21: opening, 23: solder bump, 24: metal block, 25: solder, 26: ground conductor film, 27: internal-submodule ground conductor, 31: first component, 32: second component, 33: third component, 34, 35, 39: component, 41: internal shield top surface portion, 42: side surface portion, 45: ground connection conductor, 81, 81i: submodule, 101, 102, 103, 104, 105, 106, 107, 108, 109, 110, 111, 112, 113, 114, 115: module

1. A module comprising:
a main board including a first surface;
a submodule mounted on the first surface;
a first component mounted on the first surface separately from the submodule;
a first sealing resin disposed so as to cover the first surface, the submodule, and the first component; and
an external shield film disposed so as to cover a surface of the first sealing resin on a side farther from the first surface, side surfaces of the first sealing resin, and side surfaces of the main board,
wherein the submodule includes a second component, a second sealing resin disposed so as to cover the second component, and an internal shield film disposed so as to cover at least a part of side surfaces of the second sealing resin, and the internal shield film has at least a two-layer structure.

2. The module according to claim 1, wherein the second component is disposed along a surface on a side closer to the first surface of the submodule, and the second component is mounted on the first surface.

3. The module according to claim 1, wherein the submodule includes a submodule board, the second component is mounted on the submodule board, and the submodule board is mounted on the first surface.

4. The module according to claim 1, wherein the internal shield film further covers a surface of the second sealing resin on a side farther from the first surface.

5. The module according to claim 1, wherein the internal shield film does not cover the surface of the second sealing resin on the side farther from the first surface, and the external shield film directly covers the surface of the second sealing resin on the side farther from the first surface.

6. The module according to claim 1, wherein the internal shield film does not cover a portion of the side surfaces of the second sealing resin, and the external shield film directly covers at least a part of the portion of the side surfaces of the second sealing resin not covered with the internal shield film.

7. The module according to claim 1, wherein the two-layer structure includes a stainless steel film and a copper film stacked in order from an inside.

8. The module according to claim 1, wherein a thickness of the internal shield film is less than or equal to a thickness of the external shield film.

9. The module according to claim 1, comprising a portion in which a part of the internal shield film and a part of the external shield film overlap each other while being in close contact with each other.

10. The module according to claim 1, wherein the main board includes a second surface as a surface opposite to the first surface, and
the module includes a third component mounted on the second surface.

11. A module comprising:
a main board including a first surface and a second surface, the second surface being opposite to the first surface;
a submodule mounted on the first surface;
a first component mounted on the first surface separately from the submodule;
a first sealing resin disposed to cover the first surface, the submodule, and the first component;
the submodule including a second component, a second sealing resin disposed so as to cover the second component, and an internal shield film disposed so as to cover at least one of side surfaces of the second sealing resin, wherein the internal shield film further includes an internal shield top surface portion covering a surface of the second sealing resin on a side farther from the first surface,
a third component mounted on the second surface;
a third sealing resin disposed so as to cover the second surface and the third component;
an external shield film disposed so as to cover side surfaces of the first sealing resin, side surfaces of the main board, a surface of the third sealing resin on a side farther from the second surface, and side surfaces of the third sealing resin; and
a ground connection conductor electrically connected to the internal shield top surface portion,
wherein the ground connection conductor penetrates the first sealing resin, and is exposed to an outside of the module.

12. The module according to claim 11, wherein the second component is disposed along a surface on a side closer to the first surface of the submodule, and the second component is mounted on the first surface.

13. The module according to claim 11, wherein the submodule includes a submodule board, the second component is mounted on the submodule board, and the submodule board is mounted on the first surface.

14. The module according to claim 11, wherein the ground connection conductor includes a solder bump.

15. The module according to claim 11, wherein the ground connection conductor includes a metal pin or a metal block.

16. The module according to claim 15, wherein the ground connection conductor includes a ground conductor film extending along a surface of the first sealing resin on a side farther from the board, and the ground conductor film is electrically connected to the metal pin or the metal block.

17. The module according to claim 11, wherein
the ground connection conductor includes:
an internal-submodule ground conductor abutting on a portion of the internal shield film disposed to cover the side surfaces of the second sealing resin so as to be electrically connected from an inside of the internal shield film; and
a solder bump connected to an end of the internal-submodule ground conductor on a side farther from the first surface, and
the solder bump penetrates the internal shield film, and is exposed to the outside of the module.

18. The module according to claim 2, wherein the internal shield film further covers a surface of the second sealing resin on a side farther from the first surface.

19. The module according to claim 3, wherein the internal shield film further covers a surface of the second sealing resin on a side farther from the first surface.

20. The module according to claim 2, wherein the internal shield film does not cover the surface of the second sealing resin on the side farther from the first surface, and the external shield film directly covers the surface of the second sealing resin on the side farther from the first surface.
